(19) United States
(12) Patent Application Publication
(10) Pub. No.: US 2025/0201508 A1
(43) Pub. Date: Jun. 19, 2025

(54) Natural Frequency Adjuster For Extraction Electrodes

(71) Applicant: Applied Materials, Inc., Santa Clara, CA (US)

(72) Inventors: Adam M. McLaughlin, Merrimac, MA (US); Jack Joseph LoPiccolo, Gloucester, MA (US)

(21) Appl. No.: 18/542,905

(22) Filed: Dec. 18, 2023

(51) Int. Cl. H01J 37/08; H01J 37/147; H01J 37/317

(52) U.S. Cl. CPC H01J 37/08; H01J 37/1472; H01J 37/3171; H01J 2237/24585

(57) ABSTRACT

A system for adjusting the natural frequency of an extraction electrode assembly is disclosed. The extraction electrode assembly typically includes at least two electrodes, attached to electrode mounting hardware, which provides electrical isolation, physical positioning and electrical connections. By disposing a mass on one or more of the electrodes, the natural frequency of the extraction electrode assembly may be adjusted. In some embodiments, the masses may be disposed at one of a plurality of different locations on the electrodes. The electrodes may include slots wherein the masses may be slid along the slots so as to adjust the natural frequency in a beneficial manner. In other embodiments, the weight of the mass may be varied to adjust the natural frequency.

### FIELD

Embodiments of the present disclosure relate to a system and method for adjusting the natural frequency of extraction electrodes for an ion implanter.

### BACKGROUND

Ion implantation common technique to introduce impurities into a workpiece to affect the conductivity of portions of that workpiece. For example, ions that contain elements in Group III, such as boron, aluminum and gallium, may be used to create P-type regions in a silicon workpiece. Ions that contain elements in Group V, such as phosphorus and arsenic, may be used to create N-type regions in the silicon workpiece.

In some systems, a spot ion beam is scanned across the workpiece to implant the ions. The scan speed may determine the amount of ions that each portion of the workpiece receives. For example, at higher scan speeds, the beam current of an area is reduced, since the ion beam spends less time over this area. Lower scan speeds allow more ions to be implanted in an area. In other embodiments, a ribbon ion beam is directed toward the workpiece to implant the ions.

In both embodiments, there is an ion source that is used to generate the ions. An extraction electrode assembly is disposed outside the ion source. The extraction electrodes are typically biased at voltages different from the ion source such that ions from within the ion source are attracted by the extraction electrode assembly and pass through the extraction aperture in the ion source.

The extraction electrode assembly is disposed close to the ion source and in some embodiments, is held in place using a cantilever configuration where only one end of the extraction electrode assembly is fixed in place. This configuration causes the extraction electrode assembly to have one or more natural frequencies, which is expected. However, in certain embodiments, one or more of these modes may coincide with the operating frequency of other components, such as pumps, motors or electrical power lines.

Therefore, it would be advantageous if there were a system that allowed the natural frequency of the extraction electrode assembly to be adjusted to avoid these undesirable frequencies. Further, it would be beneficial if this adjustment could be readily performed at a customer location, if desired.

### SUMMARY

A system for adjusting the natural frequency of an extraction electrode assembly is disclosed. The extraction electrode assembly typically includes at least two electrodes, attached to electrode mounting hardware, which provides electrical isolation, physical positioning and electrical connections. By disposing a mass on one or more of the electrodes, the natural frequency of the extraction electrode assembly may be adjusted. In some embodiments, the masses may be disposed at one of a plurality of different locations on each of the electrodes. The electrodes may include slots wherein the masses may be slid along the slots so as to adjust the natural frequency in a beneficial manner. In other embodiments, the weight of the mass may be varied to adjust the natural frequency.

According to one embodiment, an extraction electrode assembly is disclosed. The extraction electrode assembly comprises a suppression electrode; a ground electrode; and electrode mounting hardware, in physical and electrical contact with the suppression electrode and the ground electrode in a cantilever configuration; wherein at least one of the suppression electrode or the ground electrode includes one or more attachment points to which a mass may be affixed so as to adjust a natural frequency of the extraction electrode assembly. In some embodiments, the mass is affixed to one of the one or more attachment points. In certain embodiments, the mass is adapted to be disposed in one of a plurality of different locations. In some embodiments, the suppression electrode and the ground electrode both include one or more attachment points to which the mass may be affixed. In certain embodiments, the mass is affixed to at least one of the one or more attachment points. In some embodiments, the one or more attachment points comprise an elongated slot, wherein a fastener passes through the elongated slot and secures the mass to a respective electrode, and wherein the mass is operable to be moved along the elongated slot to different positions. In some embodiments, the one or more attachment points comprises a plurality of holes, wherein a fastener passes through one of the plurality of holes to secure the mass to a respective electrode. In some embodiments, the extraction electrode assembly includes a second mass, wherein the mass and the second mass are magnetic and are disposed on opposite sides of a respective electrode at one of the one or more attachment points.

According to another embodiment, an ion implantation system is disclosed. The ion implantation system comprises an extraction electrode assembly, comprising: electrode mounting hardware; a suppression electrode, wherein the suppression electrode comprises: a suppression handle attached to the electrode mounting hardware at a proximal end; a rounded end located at a distal end of the suppression handle; and a suppression aperture disposed in the rounded end, aligned with the extraction aperture; and a ground electrode, wherein the ground electrode comprises: a ground handle attached to the electrode mounting hardware at a proximal end; a rounded end located at a distal end of the ground handle; and a ground aperture disposed in the rounded end, aligned with the extraction aperture and the suppression aperture; wherein one or more attachment points are disposed in the suppression handle and the ground handle, each attachment point operable to have a mass affixed thereto, so as to adjust a natural frequency of the extraction electrode assembly; a mass analyzer; and one or more beamline components to direct the ions toward a workpiece. In some embodiments, the one or more attachment points comprise an elongated slot, wherein a fastener passes through the elongated slot and secures the mass to a respective electrode, and wherein the mass is operable to be moved along the elongated slot from a first position closest to the rounded end to a second position closest to the electrode mounting hardware. In some embodiments, the one or more attachment points comprise a plurality of holes, wherein a fastener passes through one of the plurality of holes to secure the mass to a respective electrode. In certain embodiments, the plurality of holes comprises at least a first hole closest to the rounded end and a second hole closest to the electrode mounting hardware. In some embodiments, two magnetic masses are disposed on opposite sides of a respective handle at one of the one or more attachment points, wherein attractive forces secure the two magnetic masses to the respective handle. In some embodiments, a mass affixed to at least one of the one or more attachment points. In some embodiments, the mass is adapted to be disposed in one of a plurality of different locations.

According to another embodiment, an extraction electrode assembly is disclosed. The extraction electrode assembly comprises electrode mounting hardware; a suppression electrode, wherein the suppression electrode comprises: a suppression handle attached to the electrode mounting hardware at a proximal end; a rounded end located at a distal end of the suppression handle; and a suppression aperture disposed in the rounded end; and a ground electrode, wherein the ground electrode comprises: a ground handle attached to the electrode mounting hardware at a proximal end; a rounded end located at a distal end of the ground handle; and a ground aperture disposed in the rounded end, aligned with the suppression aperture; wherein a threaded shaft is disposed in at least one of the suppression handle and the ground handle in a direction extending from the electrode mounting hardware to the rounded end; and a threaded mass disposed on the threaded shaft so as to adjust a natural frequency of the extraction electrode assembly. In some embodiments, the threaded mass travels from a first position closest to the rounded end to a second position closest to the electrode mounting hardware. In some embodiments, the threaded shaft is disposed in both the suppression handle and the ground handle.

According to another embodiment, an ion implantation system is disclosed. The ion implantation system comprises an ion source having an extraction aperture to generate ions; the extraction electrode assembly described above; a mass analyzer; and one or more beamline components to direct the ions toward a workpiece.

### BRIEF DESCRIPTION OF THE FIGURES

For a better understanding of the present disclosure, reference is made to the accompanying drawings, which are incorporated herein by reference and in which:

FIG. 1 is an ion implanter according to one embodiment;

FIG. 2A shows the extraction electrode assembly as viewed from the ion source according to one embodiment;

FIG. 2B shows the extraction electrode of FIG. 2A as seen looking toward the ion source;

FIG. 3A shows the extraction electrode assembly of FIG. 2A with a mass installed in the suppression electrode;

FIG. 3B shows the extraction electrode assembly of FIG. 2A with a mass installed in the ground electrode;

FIGS. 4A-4B shows a cross-section of the extraction electrode assembly according to other embodiments;

FIG. 5A shows the extraction electrode assembly as viewed from the ion source according to a fourth embodiment;

FIG. 5B shows the extraction electrode of FIG. 5A as seen looking toward the ion source; and

FIG. 6 shows the extraction electrode assembly as seen looking toward the ion source according to a fifth embodiment.

### DETAILED DESCRIPTION

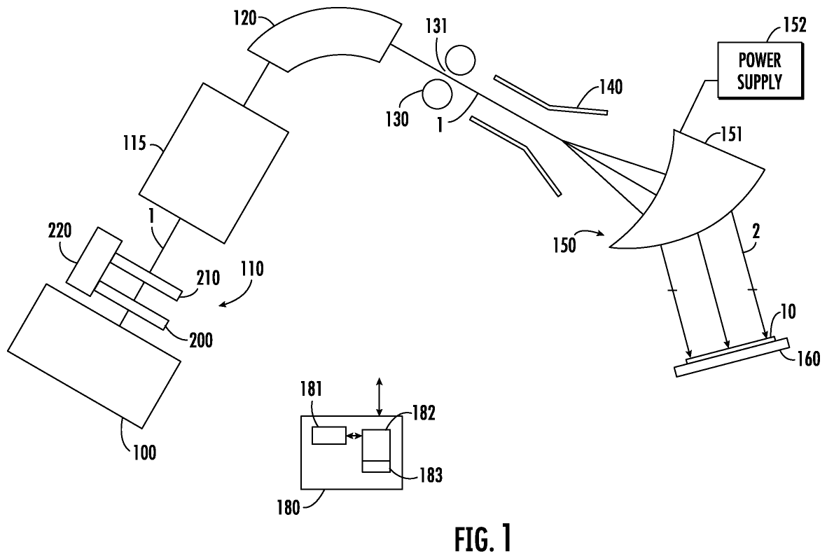

As noted above, an extraction electrode assembly is disposed outside an ion source and is used to extract ions from within the ion source. FIG. 1 shows an ion implantation system that creates a spot beam that may be used for implanting ions into a workpiece using an extraction electrode assembly according to one embodiment.

The ion implantation system includes an ion source 100 comprising a plurality of chamber walls defining an ion source chamber. In certain embodiments, the ion source 100 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed.

In another embodiment, a cathode is disposed within the ion source chamber. A filament is disposed behind the cathode and energized so as to emit electrons. These electrons are attracted to the cathode, which in turn emits electrons into the ion source chamber. This cathode may be referred to as an indirectly heated cathode (IHC), since the cathode is heated indirectly by the electrons emitted from the filament.

Other embodiments are also possible. For example, the plasma may be generated in a different manner, such as by a Bernas ion source, a capacitively coupled plasma (CCP) source, microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions 1 generated in the ion source chamber are extracted and directed toward a workpiece 10. The extraction aperture may be any suitable shape. In certain embodiments, the extraction aperture may be oval or rectangular shaped.

Disposed outside and proximate the extraction aperture of the ion source 100 is the extraction electrode assembly 110. The extraction electrode assembly 110 may include a suppression electrode 200, which is disposed closest to the ion source 100 and a ground electrode 210. The two electrodes may be maintained in position through the use of electrode mounting hardware 220.

Located downstream from the extraction electrode assembly 110 is a mass analyzer 120. An acceleration/deceleration column 115 may be positioned between extraction electrode assembly 110 and mass analyzer 120. The mass analyzer 120 uses magnetic fields to guide the path of the extracted ions 1. The magnetic fields affect the flight path of ions according to their mass and charge. A mass resolving device 130 that has a resolving aperture 131 is disposed at the output, or distal end, of the mass analyzer 120. By proper selection of the magnetic fields, only those ions 1 that have a selected mass and charge will be directed through the resolving aperture 131. Other ions will strike the mass resolving device 130 or a wall of the mass analyzer 120 and will not travel any further in the system. The ions that pass through the mass resolving device 130 may form a spot beam.

One or more beamline components may be disposed downstream from the mass resolving device 130 to direct the ions 1 toward the workpiece 10.

In certain embodiments, the spot beam may then enter a scanner 140 which is disposed downstream from the mass resolving device 130. The scanner 140 causes the spot beam to be fanned out into a plurality of divergent ion beamlets. In other words, the scanner 140 creates diverging ion trajectory paths. The scanner 140 may be electrostatic or magnetic. The scanner 140 may comprise spaced-apart scan plates connected to a scan generator. The scan generator applies a scan voltage waveform, such as a sawtooth waveform, for scanning the ion beam in accordance with the electric field between the scan plates. Angle corrector 150 is designed to deflect ions in the scanned ion beam to produce scanned ion beam 2 having parallel ion trajectories, thus focusing the scanned ion beam. Specifically, the angle corrector 150 is used to alter the diverging ion trajectory paths into substantially parallel paths of a scanned ion beam 2. In particular, angle corrector 150 may comprise magnetic pole pieces 151 which are spaced apart to define a gap and a magnet coil (not shown) which is coupled to a power supply 152. The scanned ion beam 2 passes through the gap between the magnetic pole pieces 151 and is deflected in accordance with the magnetic field in the gap. The magnetic field may be adjusted by varying the current through the magnet coil. Beam scanning and beam focusing are performed in a selected plane, such as a horizontal plane.

The workpiece 10 is disposed on a movable workpiece holder 160.

In certain embodiments, the forward direction of the ion beam is referred to as the Z-direction, the direction perpendicular to this direction may be referred to as the first direction or the X-direction, while the direction perpendicular to the Z-direction and the X-direction may be referred to as the second direction or the Y-direction. In this example, it is assumed that the scanner 140 scans the spot beam in the first direction while the movable workpiece holder 160 is translated in the second direction. The rate at which the scanner 140 scans the spot beam in the first direction may be referred to as beam scan speed or simply scan speed.

Thus, in operation, the movable workpiece holder 160 moves in the second direction from a first position, which may be above the scanned ion beam 2 to a second position, which may be below the scanned ion beam 2. The movable workpiece holder 160 then moves from the second position back to the first position. During this time, the spot beam is being scanned in the first direction, ensuring that the entirety of the workpiece 10 is exposed to the spot beam.

A controller 180 may be used to control the system. The controller 180 has a processing unit 181 and an associated memory device 182. This memory device 182 contains the instructions 183, which, when executed by the processing unit, enable the system to perform the functions described herein. This memory device 182 may be any non-transitory storage medium, including a non-volatile memory, such as a FLASH ROM, an electrically erasable ROM or other suitable devices. In other embodiments, the memory device 182 may be a volatile memory, such as a RAM or DRAM. In certain embodiments, the controller 180 may be a general purpose computer, an embedded processor, or a specially designed microcontroller. The actual implementation of the controller 180 is not limited by this disclosure. The controller 180 may be in communication with the scanner 140, and other components to control the system.

In other embodiments, a ribbon beam may be extracted from the ion source. These embodiments also include a mass analyzer, a mass resolving aperture and one or more beamline components to direct the ions 1 toward the workpiece 10. These components may include a collimator and an acceleration/deceleration stage.

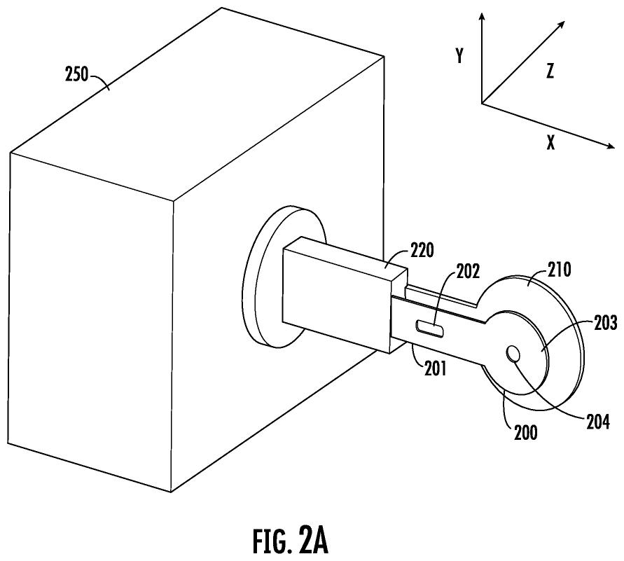

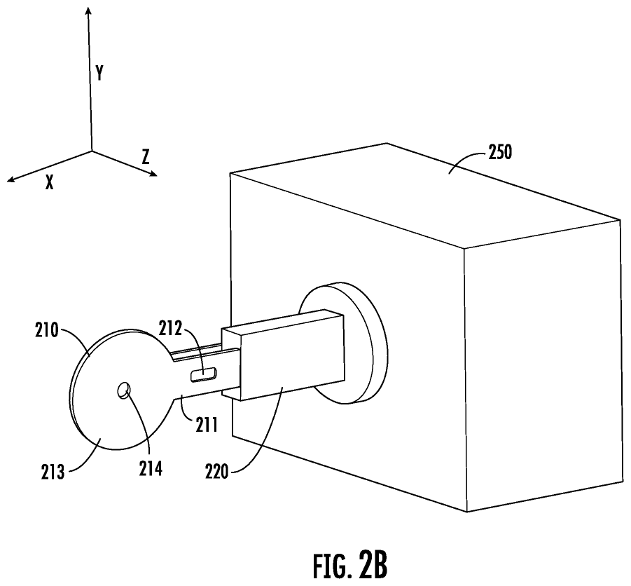

FIG. 2A shows a view of the extraction electrode assembly 110 as seen from the ion source 100. FIG. 2B shows the extraction electrode assembly 110 as seen looking toward the ion source 100. The extraction electrode assembly 110 includes a suppression electrode 200, which is disposed closest to the ion source 100. The suppression electrode 200 includes a suppression handle 201 and a rounded end 203 located at the distal end of the suppression handle 201. A suppression aperture 204 is located in the rounded end 203. This suppression aperture 204 is aligned with the extraction aperture of the ion source 100 such that ions pass through this suppression aperture 204. The suppression handle 201 includes one or more attachment points 202, which will be described in more detail below. The proximal end of the suppression handle 201 is affixed to the electrode mounting hardware 220. The electrodes extend outward from the electrode mounting hardware 220 in the X-direction.

As best seen in FIG. 2B, the ground electrode 210 is disposed downstream from the suppression electrode 200 in the Z direction. The ground electrode 210 includes a ground handle 211 and a rounded end 213 located at the distal end of the ground handle 211. A ground aperture 214 is located in the rounded end 213. This ground aperture 214 is aligned with the suppression aperture 204 and the extraction aperture of the ion source 100 such that ions pass through this ground aperture 214. The ground handle 211 includes one or more attachment points 212, which will be described in more detail below. The proximal end of the ground handle 211 is affixed to the electrode mounting hardware 220.

The electrode mounting hardware 220 performs several functions. First, it electrically isolates the suppression electrode 200 from the ground electrode 210. This may be accomplished through the use of an insulating material. Second, the electrode mounting hardware 220 provides the electrical connections to the electrodes. In certain embodiments, the suppression electrode 200 is maintained at a voltage that is negative relative to the ion source 100 so as to attract positive ions from the ion source. The ground electrode 210 may be connected to electrical ground. Third, the electrode mounting hardware 220 provides the structural support for the electrodes. Specifically, the electrode mounting hardware 220 is affixed to a movable manipulator 250 that allows translation of the extraction electrode assembly 110 in different directions to shape the beam. In this way, the electrode mounting hardware 220 is able to hold the electrodes in the desired location. Thus, the electrode mounting hardware 220 provides the physical and electrical connections for both electrodes.

Note that the suppression electrode 200 and the ground electrode 210 are only supported by the electrode mounting hardware 220 at one end.

As noted above, the extraction electrode assembly 110 may have one or more natural frequencies. In certain embodiments, it is desirable that these natural frequencies do not coincide with certain other frequencies, so that vibrations are not amplified by the extraction electrode assembly 110. For example, many pumps are known to operate at 30 Hz. Further, electrical lines and electrical motors typically operate at 50 or 60 Hz. Therefore, to avoid vibratory displacements of the extraction electrode assembly 110, it is desirable that none of the modes of the natural frequencies of the extraction electrode assembly 110 coincide with these frequencies.

The natural frequency of the extraction electrode assembly 110 may be affected by many factors, including the length of the handles, the material used to form the electrodes, and the mounting of the extraction electrode assembly 110. Consequently, it is possible that the natural frequencies of an extraction electrode assembly 110 may differ between installations. Further, any change in the material used to form the electrodes may affect the natural frequency of the extraction electrode assembly.

One approach to address this issue is to adjust the natural frequency of the extraction electrode assembly 110. This may be achieved by optionally disposing masses at one or a plurality of locations on each respective electrode.

In one embodiment, attachment points 202 and 212 are incorporated into the electrodes, and more specifically into the handles of the respective electrodes. In one embodiment, the attachment points 202 and 212 are elongated slots. These elongated slots extend in the X-direction and are dimensioned such that the shaft of a fastener, such as a screw, may pass through the slot, but the head cannot pass. The fastener may be used to secure a mass to the respective handle.

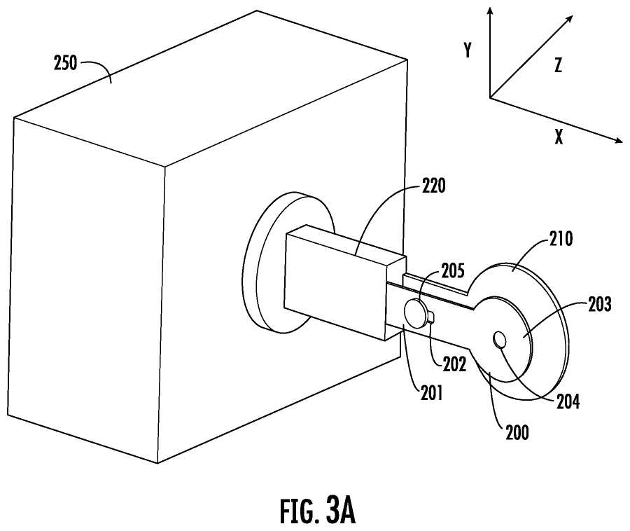

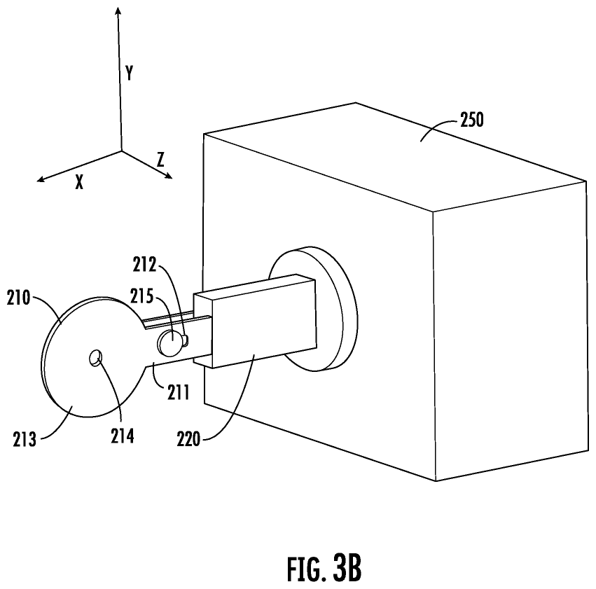

FIGS. 3A-3B show the extraction electrode assembly of FIGS. 2A-2B with a mass secured to each respective handle. FIG. 3A shows suppression mass 205 installed in the attachment point 202 using a screw, while FIG. 3B shows a ground mass 215 installed in the attachment point 212 using a screw. Note that the use of slots allows the masses to be slid closer to or further from the electrode mounting hardware 220 in the X direction, as desired. In certain embodiments, the masses may be a refractory metal. Further, in some embodiments, higher density metals, such as tungsten, may be used to allow heavier masses in a certain form factor. In some embodiments, the masses may be between 1 and 10% of the mass of the respective electrode, although other weights may be used.

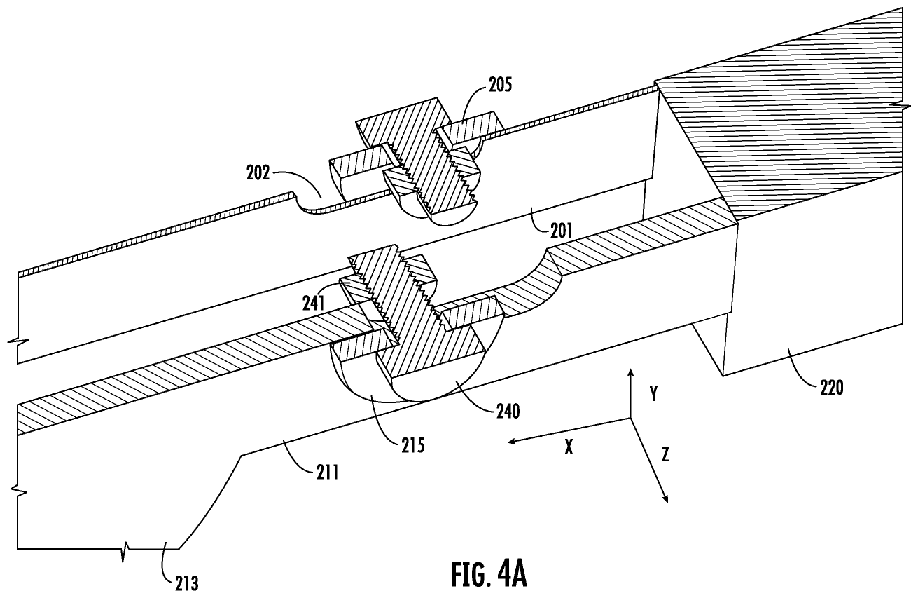

FIG. 4A shows a cross-section of the extraction electrode assembly 110. In this embodiment, the masses include a through hole such that the shaft of a screw 240 may pass through the hole and be secured with a nut 241. In another embodiment, shown in FIG. 4B, the masses may include a threaded hole, such that the shaft of the screw 240 may pass through the slot and be screwed into the threaded hole to retain the mass in position. In yet another embodiment, the mass may include an affixed fastener, such that the fastener passes through the slot and is secured with a nut. Note that the suppression mass 205 and the ground mass 215 need not be in the same position within the respective slots. In fact, independent movement of the masses allows additional configurations, which result in different adjustments to the natural frequency.

The embodiment shown in FIGS. 3A-3B is capable of at least nine configurations through the use of mass associated with each electrode, wherein each mass has at least three possible positions (near the rounded end, far from the rounded end, and not installed). It was found that, by varying the positions of these two masses, the natural frequencies may be changed by up to 20%.

Note that by using an elongated slot, there are at least two different positions, the first position located nearest the rounded end and the second position located nearest the electrode mounting hardware 220. Note that additional positions may be included by securing the mass to a location on the slot between these two positions.

The first two modes of the natural frequencies are typically lower frequencies that are more likely to coincide with other components. In one test, the use of masses allows the frequency of the first mode to change by up to 10% and the frequency of the second mode to change by more than 20%.

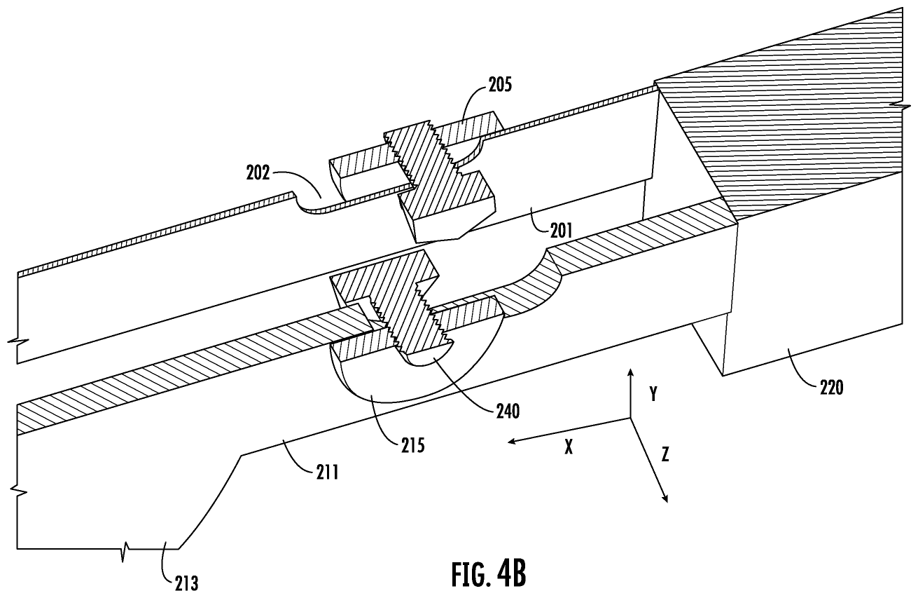

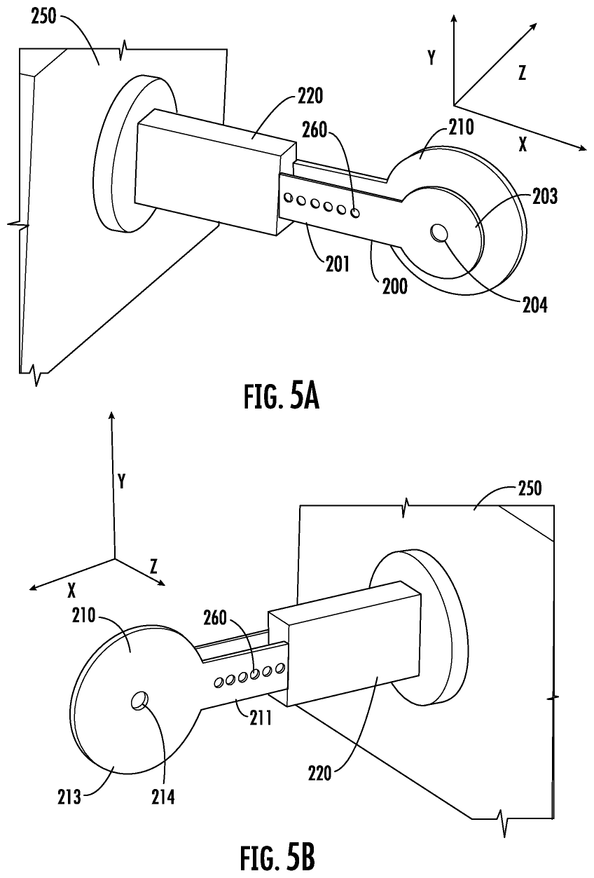

While FIGS. 2A-2B, 3A-3B and 4A-4B all show the attachment points as being an elongated slot, other embodiments are also possible. For example, in another embodiment shown in FIGS. 5A-5B, a plurality of smaller holes 260 are disposed on each handle. The plurality of smaller holes 260 may include at least a first hole located closest to the rounded end and a second hole located closest to the electrode mounting hardware 220. Additional holes may be disposed between these two holes and may be along the X-direction. The mass may be secured to one of these smaller holes 260 using any of the attachment mechanisms described above. This configuration allows the placement of the masses at discrete positions. In contrast, the use of a slot allows the masses to be positioned in a continuous set of positions. In addition, if multiple smaller holes 260 are used, multiple masses may be affixed to each of the electrodes.

Further, in the test described above, it was assumed that the masses had the same weight, which was 17 g. However, in other embodiments, different weights may be used. For example, the second mass may have twice the mass of the first mass. In fact, the use of two different weights and two different positions creates 25 different configurations that may be utilized.

While the above description discloses an attachment point on both electrodes, in certain embodiments, the attachment point may be limited to only one electrode. For example, if only the suppression electrode 200 had the one or more attachment points, the number of configurations is reduced. However, if different weights are used, the number of different configurations may be increased.

Furthermore, while the above description discloses the use of masses that are secured using screws that pass through attachment points, other embodiments are possible. For example, in another embodiment, the masses may be magnetic. The handle of each electrode may be thin enough such that magnetic masses may be placed on either side of the handle and are held in place due to the attractive force between the magnets. The magnetic masses may be moved along the respective handle to achieve a plurality of different attachment points.

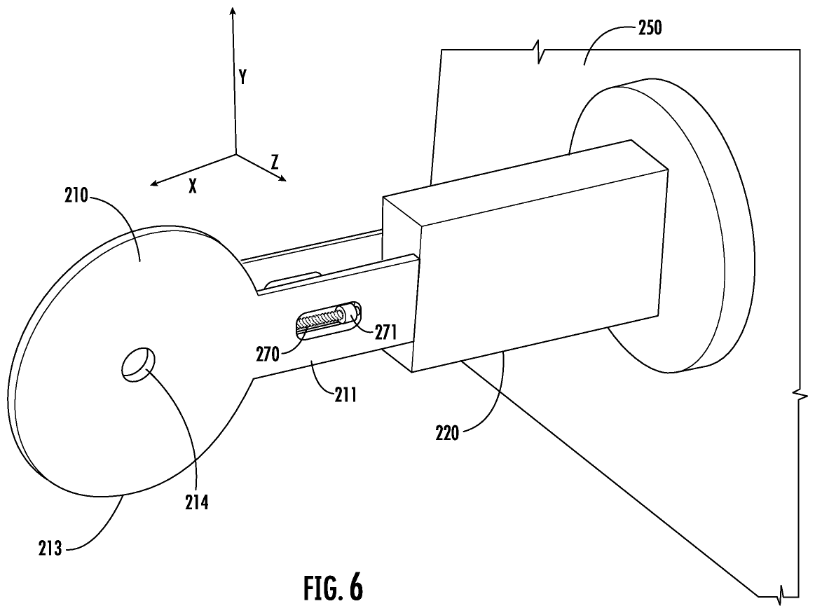

In yet another embodiment, shown in FIG. 6, a threaded shaft 270 may be disposed in the ground handle 211 and the suppression handle 201 and extend in the X direction. One or more threaded masses 271 may then be disposed on the threaded shaft 270 and rotated to move the masses along the respective handles. In some embodiments, the threaded shaft 270 is disposed in only one of the handles. Thus, like all of the embodiments above, the masses are movable in a direction that is parallel to the direction in which the electrodes extend from the electrode mounting hardware 220 such that the masses may move from a first position located closest to the rounded end to a second position located closest to the electrode mounting hardware 220.

The embodiments described above in the present application may have many advantages. As noted above, the configuration of the extraction electrode assembly may include one or more natural frequencies which result in vibrations. These frequencies may coincide with the operating frequencies of other components in the system. By adjusting the natural frequency of the extraction electrode assembly, these vibrations may be minimized. Further, the present disclosure makes use of masses that may vary in weight, position or both. These masses are removably affixed to the attachment points on the electrodes. This allows fine tuning of the natural frequencies based on the environment in which the extraction electrode assembly is disposed. As an example, in one environment, with the placement of the masses in a certain configuration, the natural frequencies of the extraction electrode assembly do not coincide with any other components. However, the natural frequencies of that same assembly in a different environment may be problematic. The ability to readily adjust the natural frequency of the extraction electrode assembly through the use and position of these masses allows this issue to be easily overcome. Further, as explained above, the masses have the ability to change the natural frequencies by up to 20%, allowing the extraction electrode assembly to be adapted to any environment.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An extraction electrode assembly, comprising:
a suppression electrode;
a ground electrode; and
electrode mounting hardware, in physical and electrical contact with the suppression electrode and the ground electrode in a cantilever configuration;
wherein at least one of the suppression electrode or the ground electrode includes one or more attachment points to which a mass may be affixed so as to adjust a natural frequency of the extraction electrode assembly.

2. The extraction electrode assembly of claim 1, further comprising the mass affixed to one of the one or more attachment points.

3. The extraction electrode assembly of claim 2, wherein the mass is adapted to be disposed in one of a plurality of different locations.

4. The extraction electrode assembly of claim 1, wherein the suppression electrode and the ground electrode both include one or more attachment points to which the mass may be affixed.

5. The extraction electrode assembly of claim 4, further comprising the mass affixed to at least one of the one or more attachment points.

6. The extraction electrode assembly of claim 2, wherein the one or more attachment points comprise an elongated slot, wherein a fastener passes through the elongated slot and secures the mass to a respective electrode, and wherein the mass is operable to be moved along the elongated slot to different positions.

7. The extraction electrode assembly of claim 2, wherein the one or more attachment points comprises a plurality of holes, wherein a fastener passes through one of the plurality of holes to secure the mass to a respective electrode.

8. The extraction electrode assembly of claim 2, further comprising a second mass, wherein the mass and the second mass are magnetic and are disposed on opposite sides of a respective electrode at one of the one or more attachment points.

9. An ion implantation system comprising:
an ion source having an extraction aperture to generate ions;
an extraction electrode assembly, comprising:
electrode mounting hardware;
a suppression electrode, wherein the suppression electrode comprises:
a suppression handle attached to the electrode mounting hardware at a proximal end;
a rounded end located at a distal end of the suppression handle; and
a suppression aperture disposed in the rounded end, aligned with the extraction aperture; and
a ground electrode, wherein the ground electrode comprises:
a ground handle attached to the electrode mounting hardware at a proximal end;
a rounded end located at a distal end of the ground handle; and
a ground aperture disposed in the rounded end, aligned with the extraction aperture and the suppression aperture;
wherein one or more attachment points are disposed in the suppression handle and the ground handle, each attachment point operable to have a mass affixed thereto, so as to adjust a natural frequency of the extraction electrode assembly;
a mass analyzer; and
one or more beamline components to direct the ions toward a workpiece.

10. The ion implantation system of claim 9, wherein the one or more attachment points comprise an elongated slot, wherein a fastener passes through the elongated slot and secures the mass to a respective electrode, and wherein the mass is operable to be moved along the elongated slot from a first position closest to the rounded end to a second position closest to the electrode mounting hardware.

11. The ion implantation system of claim 9, wherein the one or more attachment points comprise a plurality of holes, wherein a fastener passes through one of the plurality of holes to secure the mass to a respective electrode.

12. The ion implantation system of claim 11, wherein the plurality of holes comprises at least a first hole closest to the rounded end and a second hole closest to the electrode mounting hardware.

13. The ion implantation system of claim 9, further comprising two magnetic masses disposed on opposite sides of respective handle at one of the one or more attachment points, wherein attractive forces secure the two magnetic masses to the respective handle.

14. The ion implantation system of claim 9, further comprising a mass affixed to at least one of the one or more attachment points.

15. The ion implantation system of claim 14, wherein the mass is adapted to be disposed in one of a plurality of different locations.

16. An extraction electrode assembly, comprising:
electrode mounting hardware;
a suppression electrode, wherein the suppression electrode comprises:
a suppression handle attached to the electrode mounting hardware at a proximal end;
a rounded end located at a distal end of the suppression handle; and
a suppression aperture disposed in the rounded end; and
a ground electrode, wherein the ground electrode comprises:
a ground handle attached to the electrode mounting hardware at a proximal end;
a rounded end located at a distal end of the ground handle; and
a ground aperture disposed in the rounded end, aligned with the suppression aperture;
wherein a threaded shaft is disposed in at least one of the suppression handle and the ground handle in a direction extending from the electrode mounting hardware to the rounded end; and
a threaded mass disposed on the threaded shaft so as to adjust a natural frequency of the extraction electrode assembly.

17. The extraction electrode assembly of claim 16, wherein the threaded mass travels from a first position closest to the rounded end to a second position closest to the electrode mounting hardware.

18. The extraction electrode assembly of claim 16, wherein the threaded shaft is disposed in both the suppression handle and the ground handle.

19. An ion implantation system, comprising:
an ion source having an extraction aperture to generate ions;
the extraction electrode assembly of claim 16;
a mass analyzer; and
one or more beamline components to direct the ions toward a workpiece.
